(19) United States
(12) Patent Application Publication
(10) Pub. No.: US 2003/0040177 A1
(43) Pub. Date: Feb. 27, 2003

(54) Method for forming metal interconnections using electroless plating

(75) Inventors: Min Kim, Yongin-city (KR); Jong-wan Park, Seoul (KR); Seok-woo Hong, Seoul (KR); Chang-hee Shin, Pusan-city (KR)

Correspondence Address: Steven M. Mills, MILLS & ONELLO LLP, Suite 605, Eleven Beacon Street, Boston, MA, 02108, US

(73) Assignee: Samsung Electronics Co., Ltd.

(21) Appl. No.: 10/066,227

(22) Filed: Jan. 31, 2002

(30) Foreign Application Priority Data
Aug. 21, 2001 (KR) 01-50322

(51) Int. Cl. H01L 21/4763; H01L 21/44

(52) U.S. Cl. 438/678; 438/628; 438/677

(57) ABSTRACT

A diffusion barrier layer having nitrogen at least on the top surface thereof is formed before activating the diffusion barrier layer used as an underlying layer during an electroless plating process, thereby enabling catalytic metal nuclei to be densely and uniformly formed on the diffusion barrier layer during the activation of the diffusion barrier layer. In a method for forming metal interconnections, a diffusion barrier layer having a nitrogen-containing layer exposed on the top surface thereof is formed on a semiconductor substrate. Then, the surface of the diffusion barrier layer is activated, and an electroless plated layer is formed on the activated diffusion barrier layer.

### BACKGROUND OF THE INVENTION

1. Field of the Invention

The present invention relates to a method of manufacturing a semiconductor device, and more particularly, to a method for forming interconnections using electroless plating.

2. Description of the Related Art

As the integration density of semiconductor devices increases, width of metal lines in interconnections decreases and length of the lines increases. Interconnection formation techniques are of paramount importance in manufacturing highly integrated semiconductor devices. In particular, resistance capacitance (RC) delay in interconnection patterns formed from via holes, contacts or trenches having submicron dimensions and high aspect ratio adversely affects signal propagation delay.

To solve the above problem, efforts to improve the driving speed of highly integrated semiconductor devices have been made. One approach to achieve high speed and highly integrated semiconductor devices is to use copper (Cu) interconnections. Copper has relatively low resistivity and high electromigration resistance. A number of new techniques using the characteristics of copper continue to be developed.

Copper interconnections may be formed by chemical vapor deposition (CVD), physical vapor deposition (PVD), electrochemical deposition (ECD), or electroless plating. Among those methods, electroless plating generally involves forming a diffusion barrier layer on the surface of a wafer, activating the resultant surface, and plating a desired layer using a difference in ionization between an oxidizing agent and a reducing agent in a solution. Electroless plating simplifies the process by eliminating a need to form a separate seed layer, thereby reducing the manufacturing cost and improving process yield. Another advantage of electroless plating is to prevent degradation of uniformity caused by IR (resistance) drop since a plating process is performed uniformly over the entire wafer surface without requiring external power.

In electroless plating, since a metal layer is electrochemically plated directly on a diffusion barrier layer without using a separate seed layer, factors such as the microstructure of an interface between the diffusion barrier layer and the metal layer and a reaction at the interface significantly affects the characteristics of metal interconnections such as electrical properties and thermal stabilities thereof. For electroless plating, an underlying layer is activated before a plated layer is formed to form catalytic metal nuclei on the underlying layer. The catalytic metal nuclei act as a catalyst to facilitate a plating procedure. To obtain a plated layer with high reliability and excellent characteristics, the catalytic metal nuclei need to be formed uniformly and densely.

### SUMMARY OF THE INVENTION

To solve the above problems, it is an object of the present invention to provide a method for forming metal interconnections whereby catalytic metal nuclei are formed uniformly and densely on an underlying layer when the underlying layer is activated for electroless plating.

Accordingly, to achieve the above object, the present invention provides a method for forming metal interconnections. In accordance with the method, a diffusion barrier layer is formed on a semiconductor substrate. A plasma treatment is performed on the surface of the diffusion barrier layer in such a way as to increase energy on the exposed surface of the diffusion barrier layer. A plasma treated surface of the diffusion barrier layer is activated; and an electroless plated layer is formed on the activated diffusion barrier layer.

The diffusion barrier layer may be formed of Ti, Ta, Ti-nitride, or Ta-nitride. A nitrogen-containing gas is used during the plasma treatment.

In activating the surface of the diffusion barrier layer, a plurality of catalytic metal nuclei are formed on the diffusion barrier layer. The catalytic metal nuclei may be formed of Pd, Pt, Au, or Ag. In activating the surface of the diffusion barrier layer, an aqueous solution containing Pd can be used. The aqueous solution may contain PdCl₂. The surface of the diffusion barrier layer is activated at a temperature of about 40-85° C.

Preferably, an aqueous solution containing copper is used in forming the electroless plated layer. The aqueous solution may contain CuSO₄.

The method may further include forming an insulating layer pattern on the semiconductor substrate for defining a hole that exposes a conductive region of the semiconductor substrate. In this case, the diffusion barrier layer is formed on the resulting structure in which the hole has been formed so as to cover the inner walls of the hole.

In a method for forming metal interconnections according to another aspect of the present invention, a diffusion barrier layer is formed on a semiconductor substrate. A nitrogen treatment is performed on the exposed surface of the diffusion barrier layer. The nitrogen treated surface of the diffusion barrier layer is activated. An electroless plated layer is formed on the activated diffusion barrier layer.

The exposed surface of the diffusion barrier layer may be plasma treated using a nitrogen-containing gas during the nitrogen treatment. Rapid thermal processing may be performed on the exposed surface of the diffusion barrier layer in a nitrogen-containing atmosphere during the nitrogen treatment. A heat treatment may be performed on the exposed surface of the diffusion barrier layer in a nitrogen-containing gas atmosphere during the nitrogen treatment. The heat treatment may be performed in a chamber or a furnace.

In a method for forming metal interconnections according to another aspect of the present invention, a diffusion barrier layer having a nitrogen-containing layer exposed on the top surface thereof is formed on a semiconductor substrate. The surface of the diffusion barrier layer is activated. An electroless plated layer is formed on the activated diffusion barrier layer. The diffusion barrier layer may be comprised of only the nitrogen-containing layer. In this case, the nitrogen-containing layer may contain 0.01-50 atom percent nitrogen. The nitrogen-containing layer may be formed of TaN or TaSiN. Alternatively, the diffusion barrier layer may include the nitrogen-containing layer and a metal layer underlying the nitrogen-containing layer. In this case, the concentration of nitrogen in the metal layer is lower than that in the nitrogen-containing layer. The metal layer may contain 0-10 atom percent nitrogen. The nitrogen-containing layer may be formed of TaN or TaSiN, and the metal layer may be formed of Ta.

A method for forming metal interconnections according to the present invention involves pre-treating the diffusion barrier with nitrogen or forming a nitrogen-containing layer in forming the diffusion barrier layer to expose the nitrogen-containing layer on the top surface of the diffusion barrier layer before activating the diffusion barrier layer. Thus, energy on the surface of the diffusion barrier layer is increased, thereby increasing a space where catalytic metal nuclei will be formed on the diffusion barrier layer during a subsequent activation step, and consequently increasing the density and uniformity of the catalytic metal nuclei. This can improve the density and characteristics of a plated layer to be formed during a subsequent electroless plating procedure.

### BRIEF DESCRIPTION OF THE DRAWINGS

The foregoing and other objects, features and advantages of the invention will be apparent from the more particular description of a preferred embodiment of the invention, as illustrated in the accompanying drawings in which like reference characters refer to the same parts throughout the different views. The drawings are not necessarily to scale, emphasis instead being placed upon illustrating the principles of the invention.

FIGS. 1-6 are cross-sections showing steps of a method of forming metal interconnections according to a first embodiment of the present invention.

FIGS. 7 and 8 are cross-sections showing steps of a method of forming metal interconnections according to a second embodiment of the present invention.

FIGS. 9 and 10 are cross-sections showing steps of a method of forming metal interconnections according to a third embodiment of the present invention.

### DETAILED DESCRIPTION OF PREFERRED EMBODIMENTS OF THE INVENTION

In the drawings, the thickness of layers and regions are exaggerated for clarity. It will also be understood that when a layer is referred to as being “on” another layer or substrate, it can be directly on the other layer or substrate, or intervening layers may also be present.

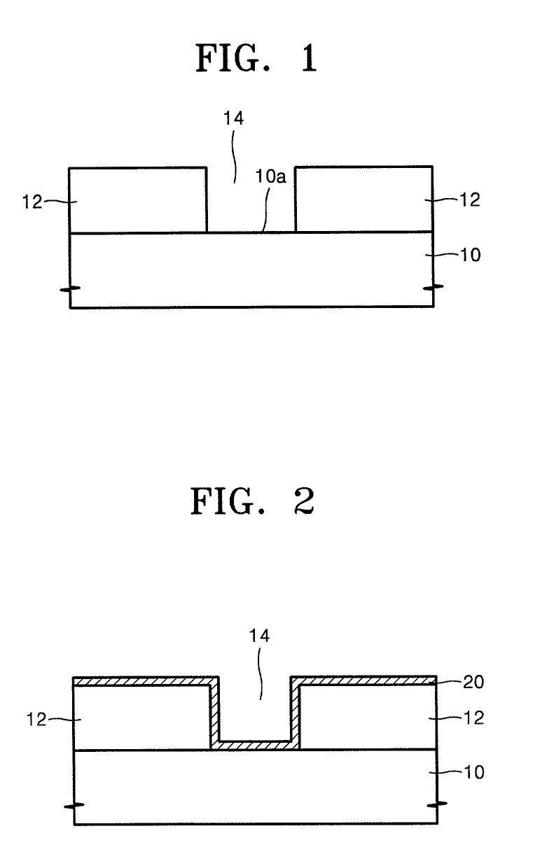

Referring to FIG. 1, an insulating layer pattern 12 is formed on a semiconductor substrate 10 so as to define a hole 14 that exposes a conductive region 10a of the semiconductor substrate 10. The hole 14 may construct a via hole, a contact hole, or a trench.

Referring to FIG. 2, a diffusion barrier layer 20 is formed on the semiconductor substrate 10 in which the hole 14 has been formed. The diffusion barrier layer 20 is formed so as to cover the inner walls of the hole 14, i.e., the conductive region 10a of the semiconductor substrate 10 and the sidewalls and top surface of the insulating layer pattern 12. The diffusion barrier layer 20 is formed so as to prevent diffusion of metal atoms from a metal layer to be formed within the hole 14 into the insulating layer pattern 12. For example, the diffusion barrier layer 20 may be formed of Ti, Ta, Ti-nitride, or Ta-nitride.

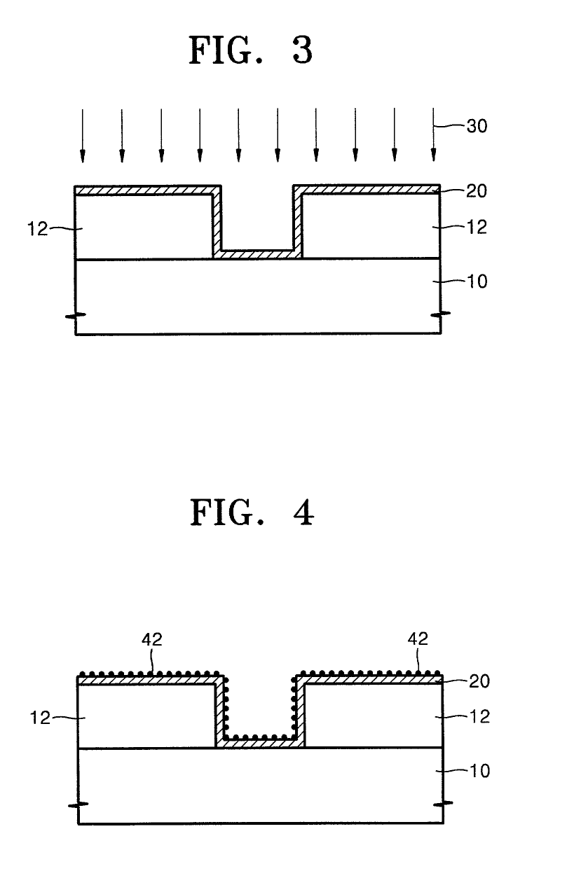

Referring to FIG. 3, in order to increase energy on the exposed surface of the diffusion barrier layer 20, the surface of the diffusion barrier layer 20 is subjected to pre-treatment 30. One method for the pre-treatment 30 may involve the use of nitride plasma. In this case, plasma treatment is performed on the surface of the diffusion barrier layer 20 using a nitrogen-containing gas such as N₂ or NH₃ at a temperature of room temperature to 500° C., preferably, 300° C. to 450° C.

Another method for the pre-treatment 30 is to perform rapid thermal process (RTP) on the exposed surface of the diffusion barrier layer 20 in a nitrogen-containing atmosphere. The RTP may be performed at a temperature of about 500° C. to about 650° C. for about 120 minutes. Still another method for the pre-treatment 30 is to heat treat the exposed surface of the diffusion barrier layer 20 in a nitrogen-containing atmosphere. The heat treatment is performed in a chamber or furnace at a temperature of about 400° C. to about 450° C.

The diffusion barrier layer 20 is pre-treated using one of the methods described above, thereby decreasing a grain size on the surface of the diffusion barrier layer 20 when the surface of the diffusion barrier layer 20 is treated with nitrogen and thus increasing the area of high energy grain boundaries. Thus, energy on the surface of the diffusion barrier layer 20 is increased, thereby increasing a space where catalytic metal nuclei are formed on the diffusion barrier layer 20 in a subsequent activation step. Consequently, this can increase the density and uniformity of the catalytic metal nuclei.

Referring to FIG. 4, the pre-treated surface of the diffusion barrier layer 20 is activated to form a plurality of catalytic metal nuclei 42 on the diffusion barrier layer 20. The plurality of catalytic metal nuclei 42 may be formed of Pd, Pt, Au, or Ag. If the catalytic metal nuclei 42 are formed of Pd, a wafer having the pre-treated diffusion barrier layer 20 is immersed in an aqueous solution containing Pd, for example, an aqueous solution of PdCl₂, in order to activate the diffusion barrier layer 20. In this case, the activation temperature is about 40-85° C. As a result of the activation, a plurality of Pd nuclei are formed densely and uniformly on the pre-treated diffusion barrier layer 20. The catalytic metal nuclei 42 act as a catalytic surface during a subsequent electroless plating process, thereby facilitating the plating process.

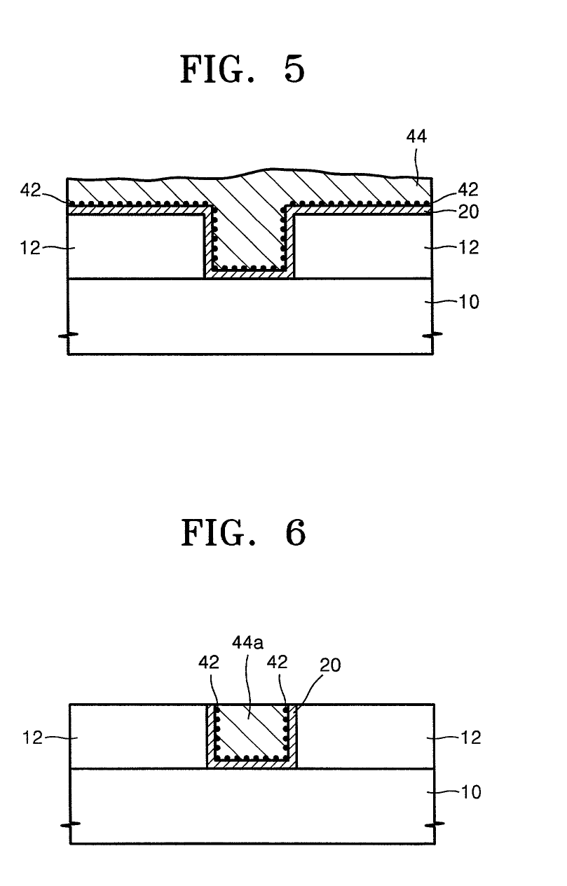

Referring to FIG. 5, an electroless plated layer 44 is formed on the diffusion barrier layer 20, activated by forming the catalytic metal nuclei 42, to fill the hole 14. The electroless plated layer 44 is preferably formed of Cu. In order to form the electroless plated layer 44, an aqueous solution containing Cu, e.g., an aqueous solution of CuSO₄, is used.

Referring to FIG. 6, chemical mechanical polishing (CMP) is performed on the resulting structure in which the electroless plated layer 44 has been formed until the top surface of the insulating layer pattern 12 is exposed. As a result of the CMP, the diffusion barrier layer 20 and the electroless plated layer 44 are left only within the hole 14 to thereby form an electroless plated pattern 44a in the hole 14. The electroless plated pattern 44a can construct a via, a contact plug, or an interconnect line required for a semiconductor device.

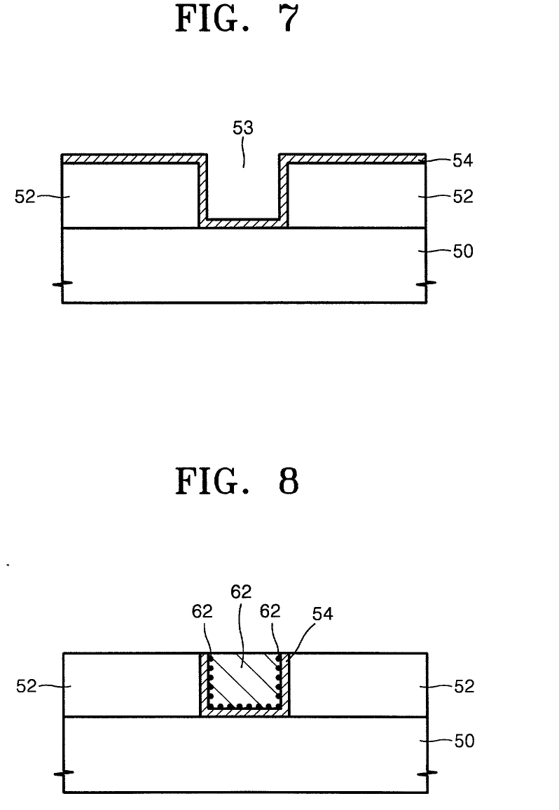

FIGS. 7 and 8 are cross-sections showing steps of a method of forming a metal interconnection according to a second embodiment of the present invention. Referring to FIG. 7, as described with reference to FIG. 1, an insulating layer pattern 52 is formed on a semiconductor substrate 50 so as to define a hole 53 that exposes a conductive region of the semiconductor substrate 50. Then, a diffusion barrier layer 54 formed comprised of a nitrogen-containing layer is formed on the semiconductor substrate 50 in which the hole 53 has been formed. The diffusion barrier layer 54 is formed so as to cover the inner walls of the hole 53, i.e., the conductive region of the semiconductor substrate 50 and the sidewalls and the top surface of the insulating layer pattern 52. Preferably, the diffusion barrier layer 54 is formed of TaN or TaSiN. Also, the nitrogen-containing layer preferably contains 0.01-50 atom percent nitrogen. The diffusion barrier layer 54 may be formed by means of sputtering.

Since the diffusion barrier layer 54 comprised of the nitrogen-containing layer contains nitrogen, a grain size on the surface of the diffusion barrier layer 54 is decreased, thereby increasing the area of grain boundaries of high energy on the surface of the diffusion barrier layer 54. Thus, energy on the surface of the diffusion barrier layer 54 is increased, thereby increasing a space where catalytic metal nuclei will be formed on the diffusion barrier layer 54 during a subsequent activation step. Consequently, this can increase the density and uniformity of the catalytic metal nuclei to be formed in the subsequent step.

Referring to FIG. 8, as described with reference to FIGS. 4-6, the surface of the diffusion barrier layer 54 is activated to form a plurality of catalytic metal nuclei 62 on the diffusion barrier layer 54. After an electroless plated layer is formed so as to fill the hole 53, CMP is performed on the resulting structure in which the electroless plated layer has been formed to form an electroless plated pattern 64 within the hole 53.

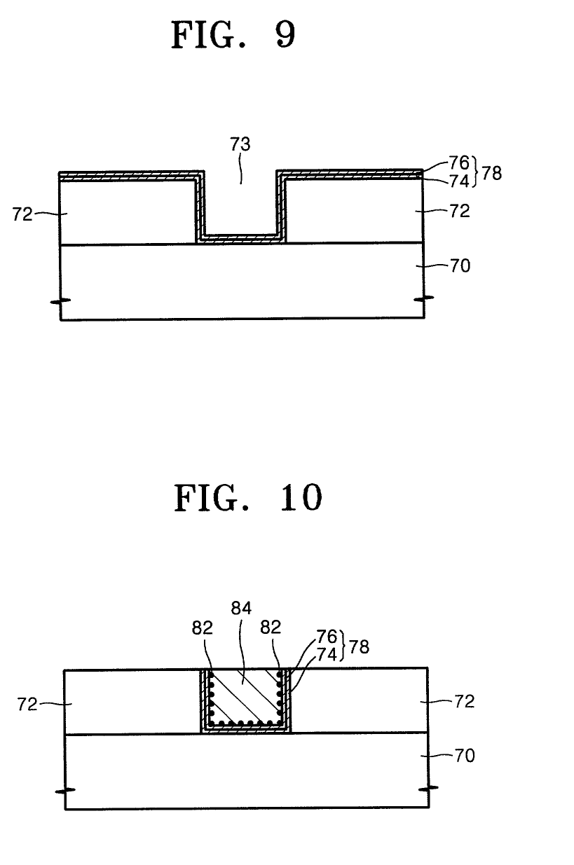

FIGS. 9 and 10 are cross-sections showing steps of a method of forming a metal interconnection according to a third embodiment of the present invention. Referring to FIG. 9, as described with reference to FIG. 1, an insulating layer pattern 72 is formed on a semiconductor substrate 70 so as to define a hole 73 that exposes a conductive region of the semiconductor substrate 70. Then, a diffusion barrier layer 78 comprised of a metal layer 74 and a nitrogen-containing layer 76 is formed on the semiconductor substrate 10 in which the hole 73 has been formed. The diffusion barrier layer 78 is formed so as to cover the inner walls of the hole 73, i.e., the conductive region of the semiconductor substrate 70 and the sidewalls and the top surface of the insulating layer pattern 72. The nitrogen-containing layer 76 of the diffusion barrier layer 78 may be formed of TaN or TaSiN. Preferably, the nitrogen-containing layer 76 of the diffusion barrier layer 78 contains 0.01-50 atom percent nitrogen. The metal layer 74 of the diffusion barrier layer 78 underlying the nitrogen-containing layer 76 contains no nitrogen or nitrogen having concentration lower than that of the nitrogen-containing layer 76. That is, the metal layer 74 contains 0-10 atom percent nitrogen. Preferably, the metal layer 74 is formed of Ta. The nitrogen-containing layer 76 and the metal layer 74 of the diffusion barrier layer 78 may be formed by means of sputtering.

Since the diffusion barrier layer 78 has the nitrogen-containing layer 76 exposed on top surface thereof, a gain size on the exposed surface of the diffusion barrier layer 78 is decreased, thereby increasing the area of high energy grain boundaries. Thus, energy on the surface of the diffusion barrier layer 78 is increased, thereby increasing a space where catalytic metal nuclei will be formed on the diffusion barrier layer 78 in a subsequent activation step and consequently increasing the density and uniformity of the catalytic metal nuclei to be formed in the subsequent step.

Referring to FIG. 10, as described with reference to FIGS. 4-6, the surface of the diffusion barrier layer 78, that is, the surface of the nitrogen-containing layer 76, is activated to form a plurality of catalytic metal nuclei 82 on the diffusion barrier layer 78. After an electroless plated layer is formed so as to fill the hole 73, CMP is performed on the resulting structure in which the electroless plated layer has been formed to form an electroless plated pattern 84 within the hole 73.

A method for forming metal interconnections according to the present invention involves pre-treating the diffusion barrier layer used as an underlying layer for performing an electroless plating procedure before activation thereof in a nitrogen atmosphere. In this case, the pre-treatment may include plasma treatment, RTP treatment, and heat treatment. Alternatively, the method involves forming a nitrogen-containing layer in forming the diffusion barrier layer to expose the nitrogen-containing layer on the top surface of the diffusion barrier layer. Thus, energy on the surface of the diffusion barrier layer is increased, thereby increasing a space where catalytic metal nuclei will be formed on the diffusion barrier layer during a subsequent activation step and consequently increasing the density and uniformity of the catalytic metal nuclei. This can improve the density and characteristics of a plated layer to be formed during a subsequent electroless plating procedure.

While this invention has been particularly shown and described with reference to preferred embodiments thereof, it will be understood by those skilled in the art that various changes in form and details may be made therein without departing from the spirit and scope of the invention as defined by the appended claims.

What is claimed is:

1. A method for forming metal interconnections, the method comprising the steps of:
forming a diffusion barrier layer on a semiconductor substrate;
performing a plasma treatment on the surface of the diffusion barrier layer in such a way as to increase energy on the exposed surface of the diffusion barrier layer;
activating a plasma treated surface of the diffusion barrier layer; and
forming an electroless plated layer on the activated diffusion barrier layer.

2. The method of claim 1, wherein the diffusion barrier layer is formed of a material selected from the group consisting of Ti, Ta, Ti-nitride, and Ta-nitride.

3. The method of claim 1, wherein a nitrogen-containing gas is used during the plasma treatment.

4. The method of claim 1, wherein in activating the surface of the diffusion barrier layer, an aqueous solution containing Pd is used.

5. The method of claim 4, wherein the aqueous solution contains PdCl₂.

6. The method of claim 1, wherein in activating the surface of the diffusion barrier layer, a plurality of catalytic metal nuclei are formed on the diffusion barrier layer.

7. The method of claim 6, wherein the catalytic metal nuclei are formed of a material selected from the group consisting of Pd, Pt, Au, and Ag.

8. The method of claim 1, wherein the surface of the diffusion barrier layer is activated at a temperature of about 40-85° C.

9. The method of claim 1, wherein in forming the electroless plated layer, an aqueous solution containing Cu is used.

10. The method of claim 9, wherein the aqueous solution contains CuSO₄.

11. The method of claim 1, wherein forming the electroless plated layer comprises the step of forming a Cu layer on the activated diffusion barrier layer.

12. The method of claim 1, further comprising the step of forming an insulating layer pattern on the semiconductor substrate for defining a hole that exposes a conductive region of the semiconductor substrate,
wherein the diffusion barrier layer is formed on the resulting structure in which the hole has been formed so as to cover the inner walls of the hole.

13. The method of claim 12, wherein the electroless plated layer is formed to fill the hole.

14. A method for forming metal interconnections, the method comprising the steps of:
forming a diffusion barrier layer on a semiconductor substrate;
performing a nitrogen treatment on an exposed surface of the diffusion barrier layer;
activating the nitrogen treated surface of the diffusion barrier layer; and
forming an electroless plated layer on the activated diffusion barrier layer.

15. The method of claim 14, wherein the diffusion barrier layer is formed of a material selected from the group consisting of Ti, Ta, Ti-nitride, and Ta-nitride.

16. The method of claim 14, wherein the exposed surface of the diffusion barrier layer is plasma treated using a nitrogen-containing gas during the nitrogen treatment.

17. The method of claim 14, wherein rapid thermal processing is performed on the exposed surface of the diffusion barrier layer in a nitrogen-containing atmosphere during the nitrogen treatment.

18. The method of claim 17, wherein the rapid thermal processing is performed at a temperature of 500-650° C.

19. The method of claim 14, wherein a heat treatment is performed on the exposed surface of the diffusion barrier layer in a nitrogen-containing gas atmosphere during the nitrogen treatment.

20. The method of claim 19, wherein the heat treatment is performed in a chamber or a furnace.

21. The method of claim 19, wherein the heat treatment is performed at a temperature of 400-450° C.

22. The method of claim 14, wherein the surface of the diffusion barrier layer is activated using an aqueous solution containing Pd.

23. The method of claim 22, wherein the aqueous solution contains PdCl₂.

24. The method of claim 14, wherein in activating the surface of the diffusion barrier layer, a plurality of catalytic metal nuclei are formed on the diffusion barrier layer.

25. The method of claim 24, wherein the catalytic metal nuclei are formed of a material selected from the group consisting of Pd, Pt, Au, and Ag.

26. The method of claim 14, wherein the surface of the diffusion barrier layer is activated at a temperature of 40-85° C.

27. The method of claim 14, wherein in forming the electroless plated layer, an aqueous solution containing Cu is used.

28. The method of claim 27, wherein the aqueous solution contains CuSO₄.

29. The method of claim 14, wherein forming the electroless plated layer comprises the step of forming a Cu layer on the activated diffusion barrier layer.

30. The method of claim 14, further comprising the step of forming an insulating layer pattern on the semiconductor substrate for defining a hole that exposes a conductive region of the semiconductor substrate,
wherein the diffusion barrier layer is formed on the resulting structure in which the hole has been formed so as to cover the inner walls of the hole.

31. The method of claim 30, wherein the electroless plated layer is formed to fill the hole.

32. A method for forming metal interconnections, the method comprising the steps of:
forming a diffusion barrier layer on a semiconductor substrate, the diffusion barrier layer having a nitrogen-containing layer exposed on the top surface thereof;
activating the surface of the diffusion barrier layer; and
forming an electroless plated layer on the activated diffusion barrier layer.

33. The method of claim 32, wherein the diffusion barrier layer is comprised of only the nitrogen-containing layer.

34. The method of claim 33, wherein the nitrogen-containing layer contains 0.01-50 atom percent nitrogen.

35. The method of claim 33, wherein the nitrogen-containing layer is formed of one of TaN and TaSiN.

36. The method of claim 34, wherein the nitrogen-containing layer is formed of one of TaN and TaSiN.

37. The method of claim 32, wherein the diffusion barrier layer includes the nitrogen-containing layer and a metal layer underlying the nitrogen-containing layer.

38. The method of claim 37, wherein the concentration of nitrogen in the metal layer is lower than that in the nitrogen-containing layer.

39. The method of claim 38, wherein the nitrogen-containing layer contains 0.01-50 atom percent nitrogen, and the metal layer contains 0-10 atom percent nitrogen.

40. The method of claim 37, wherein the nitrogen-containing layer is formed of one of TaN and TaSiN, and the metal layer is formed of Ta.

41. The method of claim 38, wherein the nitrogen-containing layer is formed of one of TaN and TaSiN, and the metal layer is formed of Ta.

42. The method of claim 39, wherein the nitrogen-containing layer is formed of one of TaN and TaSiN, and the metal layer is formed of Ta.

43. The method of claim 32, wherein an aqueous solution containing Pd is used in activating the surface of the diffusion barrier layer.

44. The method of claim 43, wherein the aqueous solution contains PdCl₂.

45. The method of claim 32, wherein a plurality of catalytic metal nuclei are formed on the diffusion barrier layer in activating the surface of the diffusion barrier layer.

46. The method of claim 45, wherein the catalytic metal nuclei are formed of a material selected from the group consisting of Pd, Pt, Au, and Ag.

47. The method of claim 32, wherein the surface of the diffusion barrier layer is activated at a temperature of 40-85° C.

48. The method of claim 32, wherein an aqueous solution containing Cu is used in forming the electroless plated layer.

49. The method of claim 48, wherein the aqueous solution contains CuSO₄.

50. The method of claim 32, wherein forming the electroless plated layer comprises the step of forming a Cu layer on the activated diffusion barrier layer.

51. The method of claim 32, further comprising the step of forming an insulating layer pattern on the semiconductor substrate for defining a hole that exposes a conductive region of the semiconductor substrate,
wherein the diffusion barrier layer is formed on the resulting structure in which the hole has been formed so as to cover the inner walls of the hole.

52. The method of claim 51, wherein the electroless plated layer is formed to fill the hole.
